(19) United States
(12) Patent Application Publication
(10) Pub. No.: US 2015/0087101 A1
(43) Pub. Date: Mar. 26, 2015

(54) METHOD FOR FORMING SEMICONDUCTOR DEVICE

(71) Applicant: Silicon Optronics, Inc., Hsinchu (TW)

(72) Inventor: Pai-Chun ZUNG, San Jose, CA (US)

(73) Assignee: Silicon Optronics, Inc., Hsinchu (TW)

(21) Appl. No.: 14/294,731

(22) Filed: Jun. 3, 2014

(30) Foreign Application Priority Data
Sep. 25, 2013 (TW) 102134454

(51) Int. Cl. H01L 27/146

(52) U.S. Cl. CPC H01L 27/14687; H01L 27/14685
USPC 438/65

(57) ABSTRACT

A method for forming a semiconductor device includes providing a wafer having a plurality of chip regions, in which each chip region includes a sensing array on a front side of the wafer. A plurality of through silicon vias is formed in the wafer from a back side of the wafer, in which the plurality of through silicon vias is electrically connected to the plurality of sensing arrays. A filter layer is formed on the plurality of sensing arrays after the plurality of through silicon vias is formed. A cover plate is attached to the front side of the wafer to cover the filter layer.

### CROSS REFERENCE TO RELATED APPLICATIONS

This Application claims priority of Taiwan Patent Application No. 102134454, filed on Sep. 25, 2013, the entirety of which is incorporated by reference herein.

### BACKGROUND OF THE INVENTION

1. Field of the Invention

The invention relates to semiconductor technologies, and in particular to a method for forming a semiconductor device having an image sensor.

2. Description of the Related Art

Low cost and module height requirements for consumer electronics has driven various wafer-level packaging schemes developed in the image sensor industry. Other packaging technologies are commonly used in the image sensor industry, but these technologies are processed at the die level. The die level processes comprise attaching chips and wire bonding the chips onto ceramic or organic substrates (and sealed with a glass lid), or directly attaching the dies onto printed circuit board substrates and wire bonding the dies.

There are two types of wafer-level package process as for image sensors. The first type is referred to as Chip Scale Packaging (CSP) or Through Silicon Via (TSV). The second type is referred to as chip on wafer, in which the image sensor chip is fabricated by a TSV process and mounted onto a second wafer.

The two types of wafer-level package processes comprise performing a series of high- and low-temperature cycling processes, such as a room temperature grinding process and a high-temperature etching process, to form through silicon vias after filter and micro lens materials are deposited on a semiconductor wafer. After a protective cover plate is attached to the semiconductor wafer, the semiconductor wafer is diced to form individual chips.

The filter and micro lens materials, however, are temperature-sensitive and less high-temperature resistant. When a relatively high temperature TSV process is performed on the semiconductor wafer, the filter and micro lens materials thereon may induce negative effects, such as performance degradation or film destruction.

Thus, there exists a need in the art for development of a method for forming a semiconductor device capable of mitigating or eliminating the aforementioned problems.

### BRIEF SUMMARY OF THE INVENTION

A detailed description is given in the following embodiments with reference to the accompanying drawings. A method for forming a semiconductor device is provided.

An exemplary embodiment of a method for forming a semiconductor device is provided. The method for forming a semiconductor device comprises providing a wafer having a plurality of chip regions, wherein each chip region includes a sensing array on the wafer. A plurality of through silicon vias are formed in the wafer, wherein the through silicon vias are electrically connected to the sensing arrays. A filter layer is formed on the sensing arrays after the through silicon vias are formed. A cover plate is attached to the wafer to cover the filter layer.

Another exemplary embodiment of a method for forming a semiconductor device is provided. The method for forming a semiconductor device comprises providing a wafer having a plurality of chip regions, wherein each chip region includes a sensing array on the wafer. A plurality of through silicon vias is formed in the wafer, wherein the through silicon vias are electrically connected to the sensing arrays. A filter layer is formed on the sensing arrays after the through silicon vias are formed. A cover plate is attached to the wafer to cover the filter layer.

According to the embodiments, the wafer-level processes are separated into three distinct process stages. The highest process temperatures for these process stages are different from each other, such as the first temperature being greater than the second temperature and the third temperature. Therefore, each process step is optimized according to materials used or filter and micro lens materials added. Moreover, after the through silicon vias are formed, fabrication of the filter layer is then performed. Therefore, the filter layer is prevented from being damaged during the TSV process at high temperatures, thereby avoiding any degrading of the performance of the filter layer and the micro lens array of the semiconductor device having image sensors. Moreover, the process for forming the dams of the cover plate, such as an etching process, is performed on the cover plate prior to attachment of the semiconductor device having the filter layer. Therefore, the required process temperature for forming the dams of the cover plate is not constrained by the relatively low process temperature for depositing the filter and micro lens materials. Furthermore, the required process temperature for attaching the cover plate does not induce negative impact on the filter layer. As a result, the performance and quality of the filter layer and the micro lens array of the semiconductor device having image sensors can be improved.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a flow diagram of an exemplary embodiment of a method for forming a semiconductor device according to the invention.

FIGS. 2 to 5 are cross-sectional views of an exemplary embodiment of a method for forming a semiconductor device according to the invention.

### DETAILED DESCRIPTION OF THE INVENTION

The following description is of a mode for carrying out the invention. This description is made for the purpose of illustrating the general principles of the invention and should not be taken in a limiting sense. The scope of the invention is best determined by reference to the appended claims. Moreover, the same or similar elements in the drawings and the description are labeled with the same reference numbers.

In order to illustrate embodiments of the invention, a front side illumination (FSI) complementary metal oxide semiconductor (CMOS) device is used as an example. However, the embodiments of the invention are not limited to any specific application.

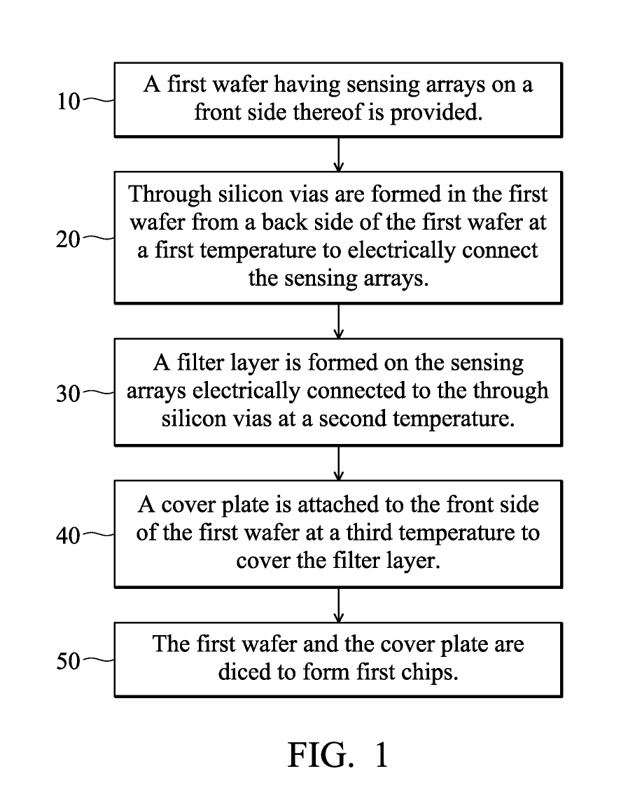

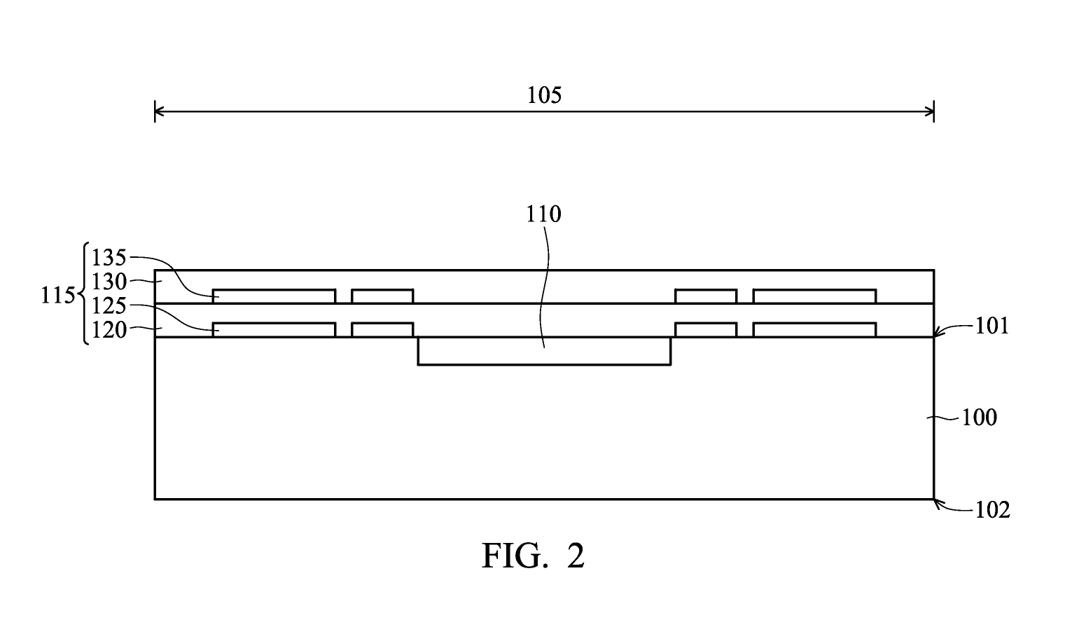

FIG. 1 is a flow diagram of an exemplary embodiment of a method for forming a semiconductor device according to the invention, and FIGS. 2 to 5 are cross-sectional views of an exemplary embodiment of a method for forming a semiconductor device according to the invention.

Referring to FIGS. 1 and 2, in an initial step 10 of a method for forming a semiconductor device, a first wafer 100 having a plurality of sensing arrays 110 on a front side 101 of the first wafer 100 is provided. The first wafer 100 may comprise silicon or other semiconductor materials, and may have a plurality of chip regions. To simplify the diagram, only one chip region 105 is depicted herein. In the embodiment, each chip region 105 has one sensing array 110 on the front side 101 of the first wafer 100. The sensing array 110 may comprise a plurality of image-sensing components, such as a photodiode, a phototransistor or other light sensors. Each chip region 105 of the first wafer 100 also has integrated circuits, such as a CMOS, a resistor or other conventional semiconductor components, to control the image-sensing components. To simplify the diagram, only a flat first wafer 100 and the sensing array 110 in the chip region 105 are depicted herein.

In one embodiment, the step 10 further comprises forming an interconnection structure 115 on the front side 101 of the first wafer 100 by deposition and patterning processes. The interconnection structure 115 comprises dielectric layers 120 and 130 and metal layers 125 and 135 formed therein. The dielectric layers 120 and 130 may comprise a single dielectric material layer, such as a silicon dioxide layer, nitride layer, oxide layer, nitrogen oxide layer, or a low-k dielectric material layer, or multi-layer dielectric material structure. The metal layers 125 and 135 may comprise electrically conductive materials, such as copper, aluminum or alloys thereof. The metal layers 125 and 135 are isolated from each other by the dielectric layers 120 and 130, and electrically connected to each other by electrically conductive plugs (not shown).

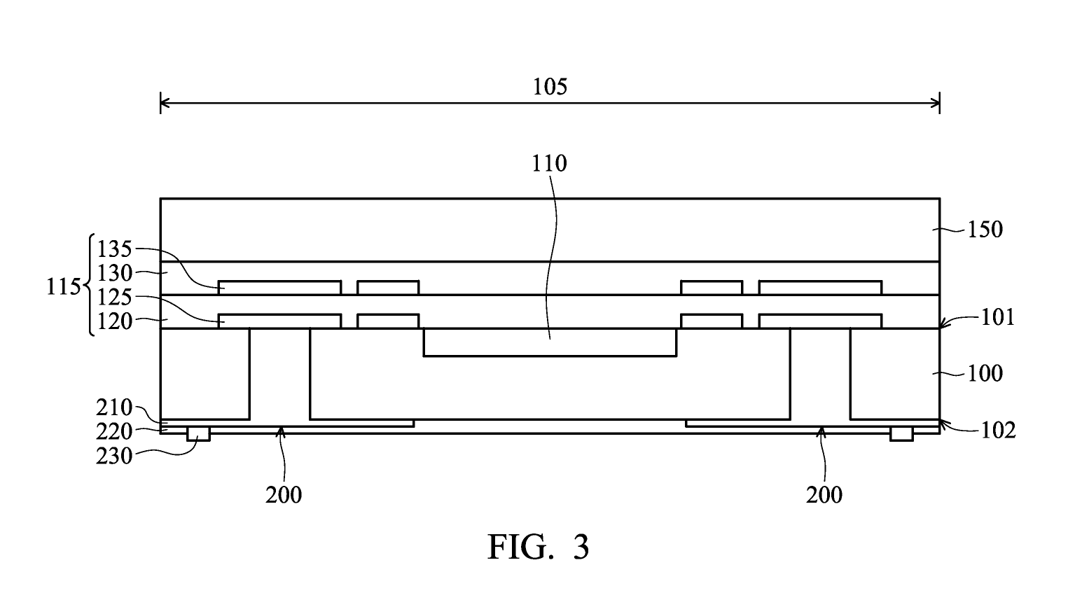

Referring to FIGS. 1 and 3, in step 20 of a method for forming a semiconductor device, a plurality of through silicon vias 200 electrically connected to the sensing array 110 is formed in the first wafer 100 from a back side 102 of the first wafer 100 at a first temperature T1. For example, a first carrier substrate 150 is attached to the interconnection structure 115 on the front side 101 of the first wafer 100. The first carrier substrate 150 may be a silicon carrier wafer, a tape or other carrier materials, such as glass or ceramic. Next, at room temperature, a wafer grinding process or a wafer thinning process, such as a mechanical wafer grinding process, a silicon etching process, a chemical mechanical polishing process or a combination thereof, is performed on the back side 102 of the first wafer 100 on the first carrier substrate 150 to reduce the thickness of the first wafer 100.

Next, a patterned mask layer (not shown) is formed on the back side 102 of the ground first wafer 100 by deposition, lithography and etching processes to define a plurality of through silicon via regions. Next, the first wafer 100 is etched from the back side 102 of the first wafer 100 to form through vias (not shown) extending through the first wafer 100 by, for example, a plasma etching process, a reactive ion etching (RIE) process or other conventional etching processes, at a higher process temperature in a range from about 160° C. to about 180° C. so as to expose a portion of the metal layer 125 in the interconnection structure 115 on the front side 101 of the first wafer 100. After the mask layer (not shown) is removed, a redistribution layer (RDL) 210 is formed on the surface of the back side 102 of the first wafer 100 and extends into the through vias (not shown) to contact the metal layer 125 in the interconnection structure 115 by a deposition process, such as a chemical plating process. As a result, an electrical connection passing the through vias from the back side 102 of the first wafer 100 to the interconnection structure 115 and the sensing array 110 is formed. Therefore, the fabrication of the plurality of through silicon vias 200 is completed. The through silicon vias 200 are electrically connected to the sensing array 110 by the metal layer 125 in the interconnection structure 115.

In one embodiment, the redistribution layer 210 may be further patterned by lithography and etching processes to form a plurality of traces (not shown) on the back side 102 of the first wafer 100, thereby providing an external electrical connection of the first wafer 100.

The redistribution layer 210 may be composed of copper or copper alloy, and may comprise a barrier layer and an adhesive layer, such as titanium nitride, tantalum nitride or the like, to prevent copper ions from diffusion. Additionally, a liner, a barrier layer, a seed layer or the like may be formed in the through vias before or after copper or other conductive material is filled into the through vias.

Next, a passivation layer 220 is formed on the surface of the back side 102 of the first wafer 100 by deposition process to cover the through silicon vias 200 and the redistribution layer 210 on the back side 102 of the first wafer 100. The passivation layer 220 may comprise silicon nitride or other passivation materials.

In the embodiment, openings (not shown) may be formed in the passivation layer 220 and a land grid array (LGA) 230 may be formed in the openings so as to form a structure electrically contacting an external device, such as another wafer, a circuit board or a package substrate. In other embodiments, the land grid array 230 may be replaced by a ball grid array (BGA).

In the embodiment, the fabrication of the through silicon vias 200 comprises high and low-temperatures cycling processes, such as a room temperature grinding process, a high-temperature etching process and a low-temperature deposition process. The highest process temperature is the first temperature T1 which is in a range from about 160° C. to about 180° C.

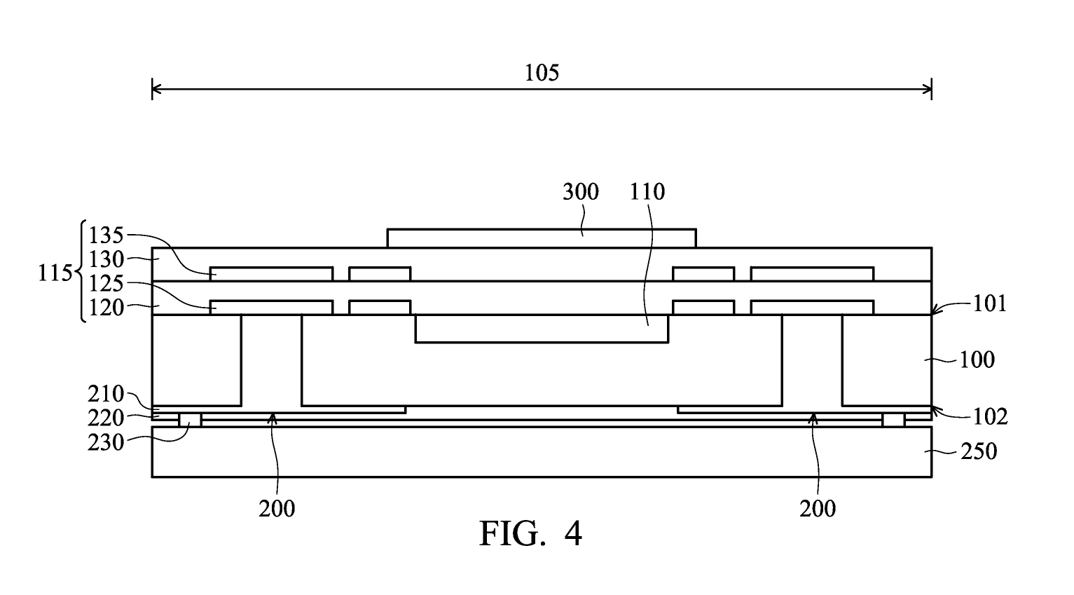

Referring to FIGS. 1 and 4, in step 30 of a method for forming a semiconductor device, a filter layer 300 is formed on the sensing array 110 electrically connecting to the through silicon vias 200 at a second temperature T2. For example, a second carrier substrate 250 is attached to the back side 102 of the first wafer 100. The first carrier substrate 150 on the first side 101 of the first wafer 100 is then removed. In the embodiment, the material of the second carrier substrate 250 may be the same as that of the first carrier substrate 150. In other embodiments, the material of the second carrier substrate 250 may be different from that of the first carrier substrate 150.

Next, the filter layer 300 is formed on the sensing array 110 electrically connecting to the through silicon vias 200 by deposition and patterning processes. In the embodiment, the highest process temperature for depositing the filter layer 300 is the second temperature T2 in a range from about 60° C. to about 100° C. In other embodiments, a method for forming a semiconductor device further comprises forming a plurality of micro lens arrays (not shown) on the filter layer 300 and corresponding to the sensing arrays 110 so as to further improve light receivability.

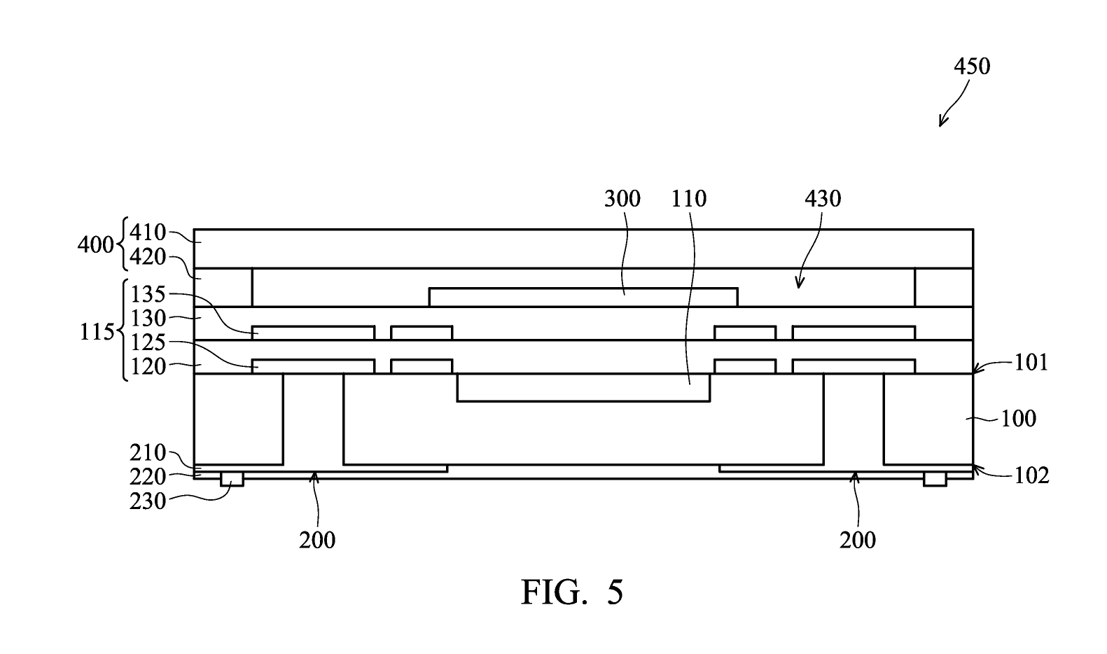

Referring to FIGS. 1 and 5, in step 40 of a method for forming a semiconductor device, a cover plate 400 is attached to the front side 101 of the first wafer 100 by adhesive glue or resin at low temperature to cover the filter layer 300, thereby protecting the image-sensing components (not shown) on the front side 101 of the first wafer 100. In the embodiment, the highest process temperature for attaching the cover plate 400 is the third temperature T3, in which the first temperature T1 is greater than the third temperature T3. For example, the third temperature T3 is less than 80° C.

In the embodiment, the cover plate 400 may comprise a transparent substrate 410 and a plurality of dams 420 on the transparent substrate 410. The dams 420 may comprise the same material as or a different material from that of the transparent substrate 410. For example, when the dams 420 comprises a different material from that of the transparent substrate 410, formation of the dams 420 comprises forming a polymer layer or a silicon layer (not shown) on the transparent substrate 410 by a deposition process. The polymer layer or the silicon layer (not shown) is patterned by an etching process to form a plurality of openings 430 exposing the transparent substrate 410 and form the dams 420 between the openings 430. In other embodiments, when the dams 420 comprise the same material as that of the transparent substrate 410, formation of the dams 420 comprises directly patterning the transparent substrate 410 to form the plurality of openings 430 in the transparent substrate 410 and form the dams 420 between the openings 430. In the embodiment, after the cover plate 400 is attached to the front side 101 of the first wafer 100, the openings 430 correspond to the filter layer 300, and the dams 420 surround the filter layer 300.

Next, in step 50, the second carrier substrate 250 is removed after the cover plate 400 is attached. The first wafer 100 and the cover plate 400 are diced along edges of the chip regions 105 to form a plurality of first chips. To simplify the diagram, only one first chip 450 is depicted herein, as shown in FIG. 5.

Organic films usually needed to be kept at a temperature lower than 100° C. However, in the typical wafer-level package processes, the relatively high temperature TSV process is performed on the semiconductor wafer having the filter and micro lens materials, such that the filter and micro lens of temperature-sensitive and less high-temperature resistant materials are easily damaged, thereby degrading the performance of the filter layer and the micro lens arrays.

In the embodiment, the wafer-level processes are separated into three distinct process stages. The first process stage is forming the through silicon vias 200 in the first wafer 100 at the first temperature T1 to electrically connect the sensing array 110. The second process stage is depositing the filter layer 300 on the sensing array 110 electrically connected to the through silicon vias 200 at the second temperature T2. The third process stage is attaching the cover plate 400 to the first wafer 100 at the third temperature T3 to cover the filter layer 300. The highest process temperatures of these process stages are different from each other. For example, the first temperature T1 is greater than the second temperature T2 and the third temperature T3. In one embodiment, the first temperature T1 is in a range from about 160° C. to about 180° C., the second temperature T2 is in a range from about 60° C. to about 100° C., and the third temperature T3 is less than 80° C. Therefore, each process step can be optimized according to materials used or filter and micro lens materials added.

According to the embodiments, after the first process stage for forming the through silicon vias 200 is completed, the second process stage for forming the filter layer 300 is then performed. Therefore, the filter layer 300 is prevented from being damaged during the TSV process at high temperature (i.e. the first temperature T1), thereby avoiding degrading the performance of the filter layer and the micro lens array of the semiconductor device having image sensors. Moreover, the process for forming the dams 420 of the cover plate 400, such as an etching process, is performed on the cover plate 400 prior to attachment of the semiconductor device having the filter layer 300. Therefore, the required process temperature for forming the dams 420 of the cover plate 400 is not constrained by the relatively low process temperature for depositing the filter and micro lens materials (i.e. the second temperature T2). Furthermore, the required process temperature for attaching the cover plate 400 (i.e. the third temperature T3) does not induce negative impact on the filter layer 300, thereby improving the performance and quality of the filter layer and the micro lens array of the semiconductor device having image sensors.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a semiconductor device, comprising:
providing a first wafer having a plurality of chip regions, wherein each chip region has a sensing array on a front side of the first wafer;
forming a plurality of through silicon vias in the first wafer from a back side of the first wafer, wherein the plurality of through silicon vias is electrically connected to the plurality of sensing arrays;
forming a filter layer on the plurality of sensing arrays after the plurality of through silicon vias is formed; and
attaching a cover plate to the front side of the first wafer to cover the filter layer.

2. The method as claimed in claim 1, wherein the plurality of through silicon vias is formed at a first temperature, the filter layer is formed at a second temperature, and the cover plate is attached at a third temperature.

3. The method as claimed in claim 2, wherein the first temperature is greater than the second temperature and the third temperature.

4. The method as claimed in claim 2, wherein the first temperature is in a range from about 160° C. to about 180° C., the second temperature is in a range from 60° C. to 100° C., and the third temperature is less than 80° C.

5. The method as claimed in claim 1, further comprising attaching a first carrier substrate to the front side of the first wafer before the plurality of through silicon vias is formed.

6. The method as claimed in claim 5, further comprising:
attaching a second carrier substrate to the back side of the first wafer after the plurality of through silicon vias is formed and before the filter layer is formed; and
removing the first carrier substrate after the second carrier substrate is attached.

7. The method as claimed in claim 6, further comprising removing the second carrier substrate after the cover plate is attached.

8. The method as claimed in claim 1, wherein the cover plate comprises a transparent substrate and a plurality of dams on the transparent substrate.

9. The method as claimed in claim 8, wherein formation of the plurality of dams comprises patterning a polymer layer or a silicon layer disposed on the transparent substrate to form a plurality of openings exposing the transparent substrate and form the plurality of dams between the plurality of openings.

10. The method as claimed in claim 8, wherein formation of the plurality of dams comprises patterning the transparent substrate to form a plurality of openings in the transparent substrate and form the plurality of dams between the plurality of openings.

11. The method as claimed in claim 1, further comprising dicing the first wafer and the cover plate along edges of the plurality of chip regions to form a plurality of first chips after the cover plate is attached.

12. The method as claimed in claim 1, further comprising forming, on the filter layer, a plurality of micro lens arrays corresponding to the plurality of sensing arrays.

13. A method for forming a semiconductor device, comprising:
providing a first wafer having a plurality of chip regions, wherein each chip region has a sensing array on the first wafer;
forming a plurality of through silicon vias in the first wafer, wherein the plurality of through silicon vias is electrically connected to the plurality of sensing arrays;
forming a filter layer on the plurality of sensing arrays after the plurality of through silicon vias is formed; and
attaching a cover plate to the first wafer to cover the filter layer.

14. The method as claimed in claim 13, wherein the plurality of through silicon vias is formed at a first temperature, the filter layer is formed at a second temperature, and the cover plate is attached at a third temperature.

15. The method as claimed in claim 14, wherein the first temperature is greater than the second temperature and the third temperature.

16. The method as claimed in claim 14, wherein the first temperature is in a range from about 160° C. to about 180° C., the second temperature is in a range from 60° C. to 100° C., and the third temperature is less than 80° C.

17. The method as claimed in claim 13, wherein the cover plate comprises a transparent substrate and a plurality of dams on the transparent substrate.

18. The method as claimed in claim 17, wherein formation of the plurality of dams comprises patterning a polymer layer or a silicon layer disposed on the transparent substrate to form a plurality of openings exposing the transparent substrate and form the plurality of dams between the plurality of openings.

19. The method as claimed in claim 17, wherein formation of the plurality of dams comprises patterning the transparent substrate to form a plurality of openings in the transparent substrate and form the plurality of dams between the plurality of openings.

20. The method as claimed in claim 13, further comprising dicing the first wafer and the cover plate along edges of the plurality of chip regions to form a plurality of first chips after the cover plate is attached.

21. The method as claimed in claim 13, further comprising forming, on the filter layer, a plurality of micro lens arrays corresponding to the plurality of sensing arrays.
